(19) United States
(12) Patent Application Publication
(10) Pub. No.: US 2021/0091328 A1
(43) Pub. Date: Mar. 25, 2021

(54) DISPLAY DEVICE

(71) Applicant: Japan Display Inc., Tokyo (JP)

(72) Inventor: Asami SAKAMOTO, Minato-ku (JP)

(73) Assignee: Japan Display Inc., Tokyo (JP)

(21) Appl. No.: 17/022,902

(22) Filed: Sep. 16, 2020

(30) Foreign Application Priority Data
Sep. 20, 2019 (JP) 2019-171582

(51) Int. Cl. H01L 51/50; H01L 51/52

(52) U.S. Cl. CPC H01L 51/5012; H01L 51/5221; H01L 51/5206

(57) ABSTRACT

A display device according to an embodiment of the present invention includes an organic light emitting layer including a light emitting material and a thermally activated delayed fluorescence material, wherein a weight percent concentration of the thermally activated delayed fluorescence material in at least one interface portion of the organic light emitting layer is lower than a weight percent concentration of the thermally activated delayed fluorescence material in an intermediate portion positioned between the one interface portion and another interface portion.

### CROSS-REFERENCE TO RELATED APPLICATION

The present application claims priority from Japanese Application JP 2019-171582 filed on Sep. 20, 2019, the content of which is hereby incorporated by reference into this application.

### BACKGROUND OF THE INVENTION

### 1. Field of the Invention

The present invention relates to a display device.

### 2. Description of the Related Art

In the related art, an organic EL display device (organic electroluminescence display) using an organic electroluminescence material (organic EL material) in a light emitting element (organic EL element) of a display unit is known. Unlike a liquid crystal display device or the like, the organic EL display device realizes a display by causing the organic EL material to emit light. The organic EL display device is a so-called a self-luminous-type display device.

The light emitting layer in this light emitting element includes an organic EL material. Moreover, by further adding the delayed fluorescence material as disclosed in JP 2013-116975 A to a light emitting layer, it is possible to increase the light emission efficiency of the light emitting layer. A technique capable of achieving the increase is disclosed.

### SUMMARY OF THE INVENTION

The light emitting layer emits light at any position of the light emitting layer in the thickness direction, and thus the light emitting layer is designed to emit light at an ideal light emitting position. The ideal light emitting position refers to a position, for example, in the same distance from the both interfaces of the light emitting layer in the thickness direction.

However, in some display devices actually manufactured, the light emitting position in the light emitting element may deviate from the ideal position. Above all, if the light emitting position is present near any one interface of the light emitting layer, the lifespan of the light emission of the light emitting element is significantly shortened.

One or more embodiments of the present invention are conceived in view of the above, and an object thereof is to provide a display device of which a defective product having a short lifespan of the light emitting element produced due to the deviation of the light emitting position is less likely to be produced.

A display device according to an embodiment of the present invention includes an organic light emitting layer including a light emitting material and a thermally activated delayed fluorescence material, wherein a weight percent concentration of the thermally activated delayed fluorescence material in at least one interface portion of the organic light emitting layer is lower than a weight percent concentration of the thermally activated delayed fluorescence material in an intermediate portion positioned between the one interface portion and another interface portion.

### BRIEF DESCRIPTION OF THE DRAWINGS

FIG. 1 is a schematic diagram illustrating a schematic configuration of an organic EL display device according to an embodiment of the present invention;

FIG. 2 is a schematic plan view illustrating an example of a display panel of the organic EL display device illustrated in FIG. 1;

FIG. 3 is a schematic view illustrating an example of a cross section taken along line III-III of FIG. 2;

FIG. 4 is an enlarged view illustrating a broken line portion in FIG. 3 according to a first example;

FIG. 5 is an enlarged view illustrating the broken line portion in FIG. 3 according to a modification example of the first example;

FIG. 6 is an enlarged view illustrating the broken line portion in FIG. 3 according to a second example;

FIG. 7 is an enlarged view illustrating the broken line portion in FIG. 3 according to a modification example of the second example;

FIG. 8 is an enlarged view illustrating the broken line portion in FIG. 3 according to a third example;

FIG. 9 is an enlarged view illustrating the broken line portion in FIG. 3 according to a modification example of the third example;

FIG. 10 is an enlarged view illustrating the broken line portion in FIG. 3 according to a modification example of the third example; and

FIG. 11 is a table summarizing light emission test results of organic EL elements.

### DETAILED DESCRIPTION OF THE INVENTION

An embodiment of the present invention will be described below with reference to the drawings. The disclosure is merely an example, and appropriate modifications while keeping the gist of the invention that can be easily conceived by those skilled in the art are naturally included in the scope of the invention. In order to make the description clearer, the width, the thickness, the shape, and the like of each part may be schematically illustrated in the drawings as compared with the actual mode, but are merely examples, and do not limit the interpretation of the present invention. In this specification and each drawing, the same elements as those already described with reference to the already-presented drawings are denoted by the same reference numerals, and detailed description thereof may be appropriately omitted.

Furthermore, in the detailed description of the present invention, when defining the positional relationship between a certain constituent and another constituent, the terms “above” and “below” not only refer to a case where the constituent is directly above or below the certain constituent but also include a case where another component is further interposed therebetween, unless otherwise specified.

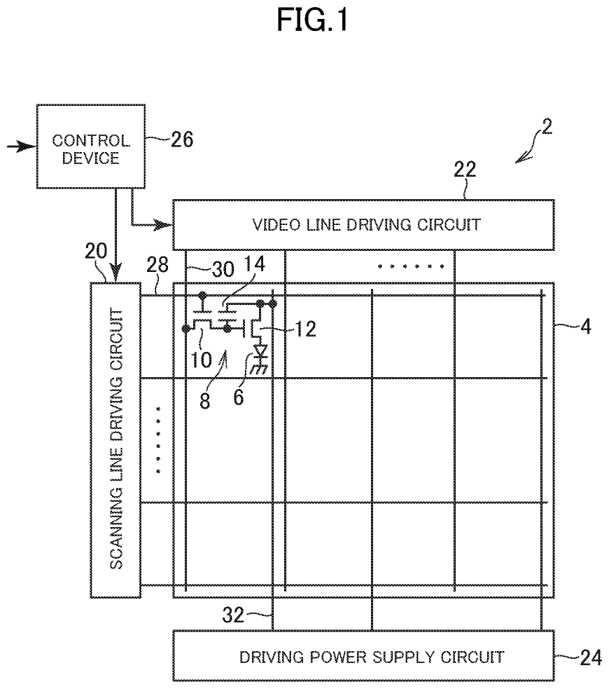

FIG. 1 is a schematic diagram illustrating a schematic configuration of a display device according to an embodiment of the present invention, as an example of an organic EL display device. An organic EL display device 2 includes a pixel array unit 4 that displays an image and a driving unit that drives the pixel array unit 4. The organic EL display device 2 is configured by forming a layered structure of a thin film transistor (TFT), an organic light emitting diode (OLED), or the like on a substrate. The schematic diagram illustrated in FIG. 1 is an example, and the present embodiment is not limited thereto.

Pixels each including OLEDs 6 and a pixel circuit 8 are disposed in the pixel array unit 4 in a matrix shape. The pixel circuit 8 is configured with a plurality of TFTs 10 and 12 and capacitors 14.

The driving unit includes a scanning line driving circuit 20, a video line driving circuit 22, a driving power supply circuit 24, and a control device 26, and controls light emission of the OLEDs 6 by driving the pixel circuit 8.

The scanning line driving circuit 20 is connected to scanning signal lines 28 provided for each arrangement in a horizontal direction of pixels (pixel row). The scanning line driving circuit 20 sequentially selects the scanning signal line 28 according to a timing signal input from the control device 26 and applies a voltage for turning on the switching TFT 10 to the selected scanning signal line 28.

The video line driving circuit 22 is connected to a video signal line 30 provided for each arrangement in a vertical direction of the pixels (pixel column). The video line driving circuit 22 receives an input of a video signal from the control device 26 and outputs a voltage corresponding to a video signal of a selected pixel row according to the selection of the scanning signal line 28 by the scanning line driving circuit 20, to each video signal line 30. The corresponding voltage is written to the capacitor 14 via the switching TFT 10 in each selected pixel row. The driving TFT 12 supplies a current corresponding to the written voltage to the OLED 6. Accordingly, the OLED 6 of a pixel corresponding to the selected scanning signal line 28 emits light.

The driving power supply circuit 24 is connected to a driving power supply line 32 provided for each pixel column and supplies the current to the OLED 6 via the driving power supply line 32 and the driving TFT 12 of the selected pixel row. The driving power supply line 32 is provided for each pixel column in FIG. 1 but may be provided for each pixel row or may be provided for both of them.

Here, a lower electrode 46 of the OLED 6 is connected to the driving TFT 12. Meanwhile, an upper electrode 50 of each OLED 6 is configured with an electrode common to the OLEDs 6 of all pixels. If the lower electrode 46 is configured as an anode, a high potential is input thereto, the upper electrode 50 becomes a cathode, and a low potential is input thereto. If the lower electrode 46 is configured as a cathode, a low potential is input thereto, the upper electrode 50 becomes an anode, and a high potential is input thereto.

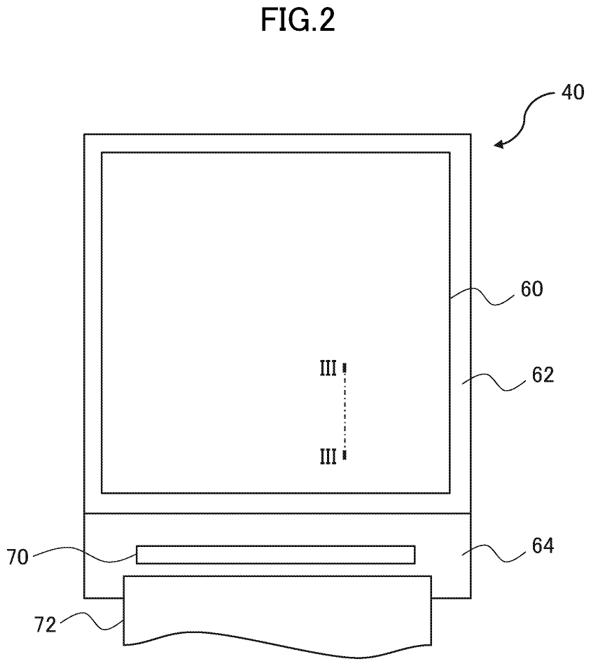

FIG. 2 is a schematic plan view illustrating an example of a display panel of the organic EL display device 2 illustrated in FIG. 1. A display area 60 of a display panel 40 is provided with the pixel array unit 4 illustrated in FIG. 1. As described above, the OLEDs 6 (light emitting units 100) are arranged on the pixel array unit 4. The upper electrodes 50 that configure the light emitting units 100 described above are formed commonly to each pixel and cover the entire display area 60. Around the display area 60, a frame area 62 is provided, and the scanning line driving circuit 20, the video line driving circuit 22, the driving power supply circuit 24, the control device 26, and the like are provided.

A terminal area 64 is provided on one side of the frame area 62 of the rectangular display panel 40. Wiring connected to the display area 60 is disposed in the terminal area 64. Further, a driver IC 70 that configures a driving unit is mounted to the terminal area 64, and a flexible printed circuit board (FPC) 72 is connected thereto. The FPC 72 is connected to the control device 26 or other circuits 20, 22, and 24, and the like, and an IC is mounted thereon.

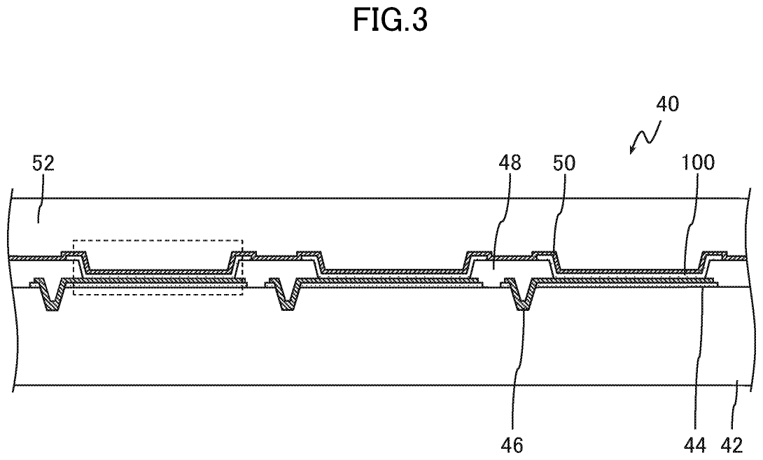

FIG. 3 is a schematic view illustrating an example of a cross section taken along line III-III of FIG. 2. The cross section taken along line III-III illustrates a cross-sectional structure in the display area 60 including NchTFTs that mainly configure pixels. In FIG. 3, for easier viewability of the cross-sectional structure, hatching of some layers is omitted.

The display panel 40 has a structure in which a TFT substrate 42 including formed TFTs, the light emitting units 100, and a sealing layer 52 sealing the light emitting units 100, and the like are layered.

For example, a protective layer (not illustrated) is disposed on the sealing layer 52. According to the present embodiment, the pixel array unit 4 has a top emission structure, and the light generated in the light emitting units 100 is emitted to the opposite side of the TFT substrate 42 (upward in FIG. 3). If a colorization method in the organic EL display device 2 is a color filter method, for example, a color filter is disposed between the sealing layer 52 and the protective layer (not illustrated) or on a counter substrate side. For example, red (R), green (G), and blue (B) light is generated by causing white light generated by the light emitting units 100 to pass through this color filter.

The TFT substrate 42 illustrated in FIG. 3 includes a substrate, an undercoat layer, a TFT, a conductive layer, a gate electrode, a source/drain electrode, and a flattening film. However, these structures are similar to the configuration in the related art, and thus individual structures are not illustrated herein, for simplification.

A passivation film 44 is formed on the TFT substrate 42. The passivation film 44 is formed, for example, with an inorganic insulating material such as SiN_{y}. Then, in the display area 60, the light emitting units 100 are formed on the passivation film 44. The pixel array unit 4 is typically formed by layering the lower electrodes 46, the light emitting units 100, and the upper electrodes 50 on the TFT substrate 42 side in this order.

If the TFTs included in the TFT substrate 42 illustrated in FIG. 3 are the driving TFTs 12 having n channels, the lower electrodes 46 are connected to the source electrodes of the TFTs. Specifically, after the flattening film is formed, contact holes for connecting the lower electrodes 46 to the TFTs are formed. For example, the lower electrodes 46 connected to the TFTs are formed for each pixel by patterning conductor units formed in the surface of the flattening film and the contact holes. The lower electrodes 46 may be formed, for example, with transparent metal oxide such as ITO or IZO. Alternatively, the lower electrodes 46 may be provided by forming a thin film of metal such as Ag, Al, or the like.

Banks 48 (also referred to as ribs), which serve as partitions of the pixel areas are formed on the structure. For example, after the lower electrodes 46 are formed, the banks 48 are formed at the pixel boundary. Thereafter, the light emitting units 100 and the upper electrodes 50 are layered in effective areas (areas where the lower electrodes 46 are exposed) of pixels surrounded by the banks 48.

The banks 48 are formed, for example, with a resin material (photosensitive acrylic or the like), in the same manner as the flattening film. Further, it is preferable that the end portions of the banks 48 have a smooth taper shape. If the opening end has a steep shape, the coverage of the light emitting units 100 becomes poor.

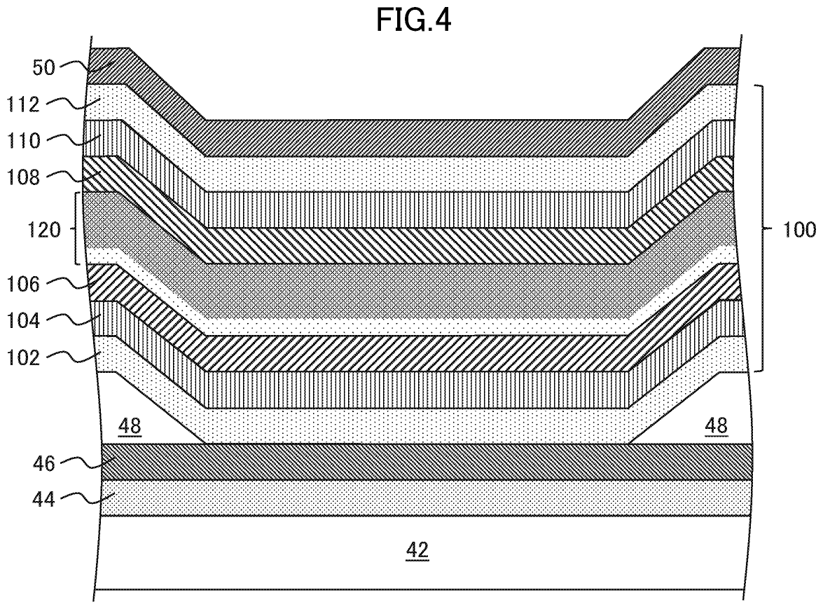

The light emitting units 100 may be continuously formed over the plurality of lower electrodes 46 and the plurality of banks 48 as illustrated in FIG. 3 or may be selectively formed on the respective lower electrodes 46. The light emitting units 100 may include a plurality of layers, and the plurality of layers are described with reference to FIG. 4.

As illustrated in FIG. 4, the light emitting unit 100 is typically formed by layering a hole transport layer 104, an organic light emitting layer 120, and an electron transport layer 110 in this order from the anode side. The light emitting unit 100 may have other layers. Examples of the other layers include a hole injection layer 102 and an electron blocking layer 106 which are disposed between the anode and the light emitting layer and an electron injection layer 112 and a hole blocking layer 108 which are disposed between the cathode and the light emitting layer. Some layers may be continuously formed over the plurality of lower electrodes 46 and the plurality of banks 48, and some other layers may be selectively formed respectively on the lower electrodes 46.

After the light emitting units 100 including a plurality of layers illustrated in FIG. 4 are formed, the upper electrodes 50 are formed as illustrated in FIG. 3. The upper electrodes 50 cover the banks 48 and the light emitting units 100. The upper electrodes 50 are provided over the plurality of pixels. Also, light emitting elements are configured with the light emitting units 100, and the lower electrodes 46 and the upper electrodes 50 which interpose the light emitting units 100. The organic light emitting layer 120 included in the light emitting unit 100 emits light by the current flowing between the lower electrode 46 and the upper electrode 50.

The upper electrode 50 is formed, for example, with a thin film of metal such as MgAg. If a metal thin film is used for the organic EL display device 2 employing the top emission structure, it is necessary to reduce the film thickness to the extent in which light can be transmitted. Meanwhile, if the organic EL display device 2 employs a bottom emission structure, the upper electrode 50 is required to be formed as a reflective electrode.

Since the top emission structure is employed herein, the upper electrode 50 is formed as a thin film of MgAg to the extent in which the light emitted from the light emitting unit 100 is transmitted. According to the exemplified order of forming the light emitting unit 100, the lower electrode 46 becomes the anode, and the upper electrode 50 becomes the cathode. The upper electrode 50 is formed over the display area 60 and a cathode contact portion provided near the display area 60 and is connected to the conductive layer of the lower layer in the cathode contact portion.

After the upper electrode 50 is formed, the sealing layer 52 is formed. The sealing layer 52 has a function of preventing moisture from entering from the outside by sealing by covering the bank 48 and the light emitting unit 100. Therefore, the sealing layer 52 has high gas barrier properties.

The sealing layer 52 has a layered structure including a first inorganic sealing film, an organic sealing film, and a second inorganic sealing film, in this order. The first inorganic sealing film is formed by forming a silicon nitride film, for example, by a CVD method. The film thickness of the first inorganic sealing film is, for example, about 1 μm. The organic sealing film is formed with a resin material such as an acrylic resin material or an epoxy-based resin material. The organic sealing film is formed by applying a curable resin composition by any appropriate method such as an inkjet method or a screen printing method and curing the obtained coating layer. The film thickness of the organic sealing film is, for example, about 10 μm. The second inorganic sealing film is formed by forming a silicon nitride film, for example, by a CVD method, in the same manner as the first inorganic sealing film. The film thickness of the second inorganic sealing film is, for example, about 1 sm.

The organic EL display device 2 is formed by the above processes. A cover glass, a touch panel substrate, or the like may be provided on the sealing layer 52, if necessary. In this case, in order to fill the gap with the organic EL display device 2, a filling material using a resin or the like may be interposed.

FIGS. 4 to 10 each are an enlarged view of the broken line portion illustrated in FIG. 3. Hereinafter, with reference to FIGS. 4 to 10, the first to third examples are described. Since the hole injection layer 102, the hole transport layer 104, the electron blocking layer 106, the hole blocking layer 108, the electron transport layer 110, and the electron injection layer 112 conform to the configurations in the related art, the descriptions thereof are omitted here. Also, the thickness of each layer in each drawing does not reflect the actual thickness, unless otherwise specified, but schematically illustrates the layer structure.

The organic light emitting layer 120 in FIGS. 4 to 10 includes an organic EL material as the light emitting material. The organic light emitting layer 120 further includes a thermally activated delayed fluorescent (TADF) material.

Examples of the TADF materials include aromatic compounds such as CZ-PS, 4CzTPN, PXZ-TRZ, and HAP-3TPA. Generally, as the TADF material included in the organic light emitting layer 120, it is particularly preferable to use a carbazolyl dicyanobenzene (CDCB) derivative. These TADF materials emit delayed fluorescence and thus have high emission efficiency. The principle is described below.

In the organic EL element, carriers are injected to the light emitting material by anodes and cathodes, and light emitting materials in an excited state are generated by recombination of the carriers, to emit light. Generally, 25% of the generated excitons is excited in the excited singlet state is, and the remaining 75% is excited in the excited triplet state. Accordingly, in a case where phosphorescence that is light emission from the excited triplet state is used, utilization efficiency of energy is higher. However, since the excited triplet state has a long lifetime, energy is deactivated due to the saturation in the excited state or interaction with excitons in the excited triplet state, and thus generally there are many cases where the quantum yield of phosphorescence is not high.

On the other hand, after the energy transitions to the excited triplet state by intersystem crossing and the like, the delayed fluorescence material causes reverse intersystem crossing to the excited singlet state by the triplet-triplet annihilation or the absorption of the thermal energy and emits fluorescence. With respect to the organic EL element, it is considered that a delayed fluorescence material thermally activated by absorbing thermal energy, that is, a TADF material is particularly useful.

If the TADF material is used for the organic EL element, the exciton in the excited singlet state emits fluorescence, as usual. Meanwhile, the exciton in the excited triplet state absorbs heat generated by the display device and causes intersystem crossing to the excited singlet, to emit fluorescence. At this time, since the light is emitted from the excited singlet, the light is emitted at the same wavelength as the fluorescence, but the lifetime of generated light (light emission lifetime) becomes longer than the general fluorescence or phosphorescence due to the reverse intersystem crossing from the excited triplet state to the excited singlet state. Therefore, the light is observed as fluorescence delayed from these. This can be defined as delayed fluorescence.

If such a thermally activated exciton transfer mechanism is used, by going through the absorption of the thermal energy after the carrier injection, the ratio of the compound in the excited singlet state which is generally generated by only 25% can be increased to 25% or more.

The organic light emitting layer 120 is a layer that emits light after the excitons are generated by the recombination of holes and electrons injected respectively from anodes and cathodes. The organic light emitting layer 120 includes the light emitting material and one or more kinds of TADF materials represented by the above examples.

The excited triplet state in the TADF material causes the reverse intersystem crossing to the excited singlet state by thermal energy of the display device or thermal energy due to becoming room temperature. Also, the energy level in the singlet exciton in the TADF material transfers to the energy level in the singlet exciton in the light emitting material. In this manner, the light emission efficiency by the light emitting material increases, and thus as the light emitting material, an organic compound of which the excited singlet energy has a lower value than the excited singlet energy of the TADF material is used.

In the organic EL element of the present invention, the light emission is mainly performed from the light emitting material included in the organic light emitting layer 120, but includes light emission from the TADF material.

The weight percent concentration of the light emitting material in the organic light emitting layer 120 is preferably 10% or less. The weight percent concentration of the TADF material in the organic light emitting layer 120 is preferably 30% or less. Moreover, the weight percent concentration of the light emitting material in the organic light emitting layer 120 is preferably lower than the weight percent concentration of the TADF material in the organic light emitting layer 120.

FIG. 4 is a view illustrating the structure of the light emitting unit 100 according to the first example by enlarging the broken line portion in FIG. 3. The first example by enlarging presents a case where the organic light emitting layer 120 is one layer.

The weight percent concentration of the TADF material in an interface portion on a lower (the lower electrode 46 which is the anode) side of the organic light emitting layer 120 illustrated in FIG. 4 is lower than the weight percent concentration of the TADF material in the intermediate portion positioned between the upper interface and the lower interface of the organic light emitting layer 120. The intermediate portion positioned between the upper interface and the lower interface of the organic light emitting layer 120 includes a position in the same distance from the both interfaces of the organic light emitting layer 120 in the thickness direction. Also, the position corresponds to the ideal light emission position designed in the organic light emitting layer 120.

In FIG. 4, the hatching on the lower surface side of the organic light emitting layer 120 is caused to be thinner than the hatching on the upper surface side. Thus, the darkness of the hatching corresponds to the height of the weight percent concentration of the TADF material.

In FIG. 4, the configuration in which the weight percent concentration of the TADF material in the lower interface portion of the organic light emitting layer 120 is lowered is disclosed, but the configuration is not limited thereto. Otherwise, the weight percent concentration of the TADF material in the interface portion on the upper (the upper electrode 50 which is the cathode) side of the organic light emitting layer 120 may be caused to be low.

In FIG. 4, the configuration including portions having a high weight percent concentration and a portion having a low weight percent concentration of the TADF material is illustrated, but the configuration is not limited thereto. For example, a concentration gradient may be set from one interface to the other interface.

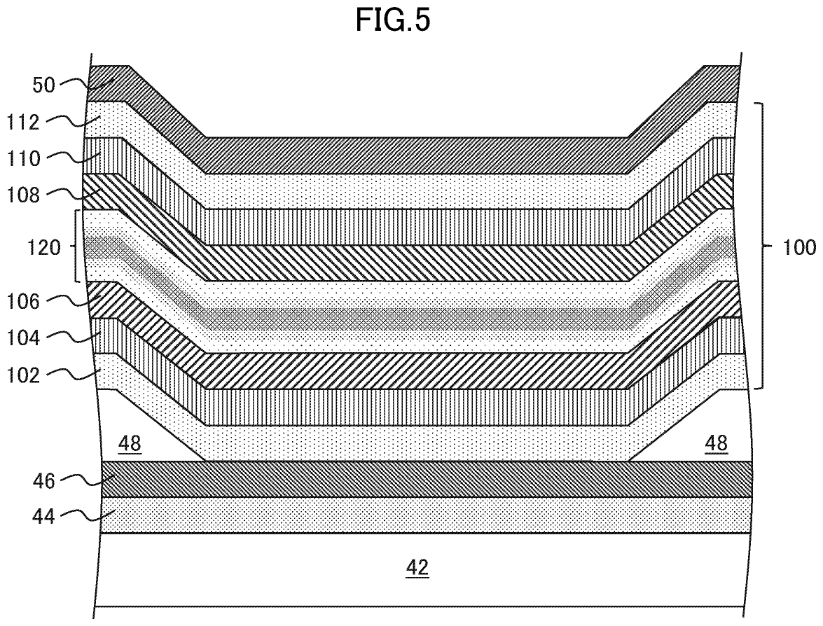

FIG. 5 illustrates a modification example of the first example illustrated in FIG. 4. FIG. 5 illustrates an example of the configuration in a case where the concentration gradient is set so that the weight percent concentration of the TADF material is the highest at the position in the same distance from the both interfaces in the thickness direction of the organic light emitting layer 120. Specifically, the concentration gradient is set so that the weight percent concentration of the TADF material is the highest in the intermediate portion positioned between the upper interface and the lower interface of the organic light emitting layer 120, and the weight percent concentration of the TADF material is the lowest in the both interface portions of the organic light emitting layer 120.

In addition to the modification example illustrated in FIG. 5, the concentration distribution may be set so that the weight percent concentration of the TADF material is the highest in the intermediate portion positioned between the upper interface and the lower interface of the organic light emitting layer 120, and the weight percent concentration of the TADF material is the lowest in any one interface portion.

As illustrated in FIGS. 4 and 5 described above, it is satisfactory as long as a structure in which the weight percent concentration of the TADF material in the organic light emitting layer 120 is changed is employed. Particularly, it is satisfactory as long as the weight percent concentration of the TADF material in at least any one interface portion of the organic light emitting layer 120 is caused to be lower than the weight percent concentration of the TADF material in the intermediate portion positioned between one interface portion and the other interface portion.

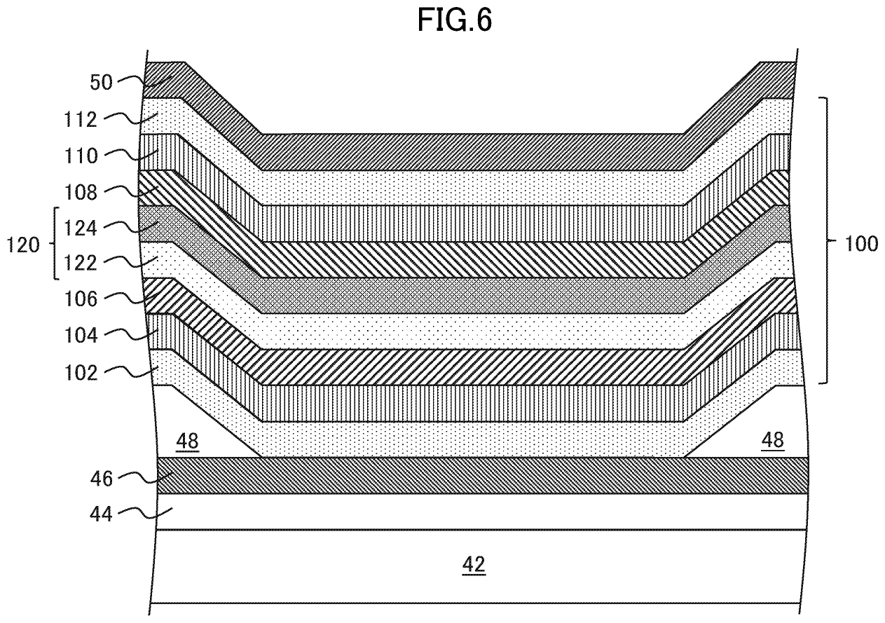

FIG. 6 is a view illustrating the structure of the light emitting unit 100 according to a second example by enlarging in the broken line portion in FIG. 3. The second example presents a case where the organic light emitting layer 120 is made of two layers of a first light emitting layer 122 and a second light emitting layer 124. FIG. 6 illustrates an example of a case where the first light emitting layer 122 is provided on a side of the lower electrode 46 which is the anode, and the second light emitting layer 124 is provided on a side of the upper electrode 50 which is the cathode. The disposition of the first light emitting layer 122 and the second light emitting layer 124 is not limited to this. Specifically, the first light emitting layer 122 may be provided on the side of the upper electrode 50 which is the cathode, and the second light emitting layer 124 may be provided on the side of the lower electrode 46 which is the anode.

The weight percent concentration of the TADF material in the first light emitting layer 122 illustrated in FIG. 6 is lower than the weight percent concentration of the TADF material in the second light emitting layer 124. Correspondingly, in FIG. 6, the hatching in the first light emitting layer 122 is caused to be thinner than the hatching in the second light emitting layer 124. In this manner, the darkness of the hatching corresponds to the height of the weight percent concentration of the TADF material.

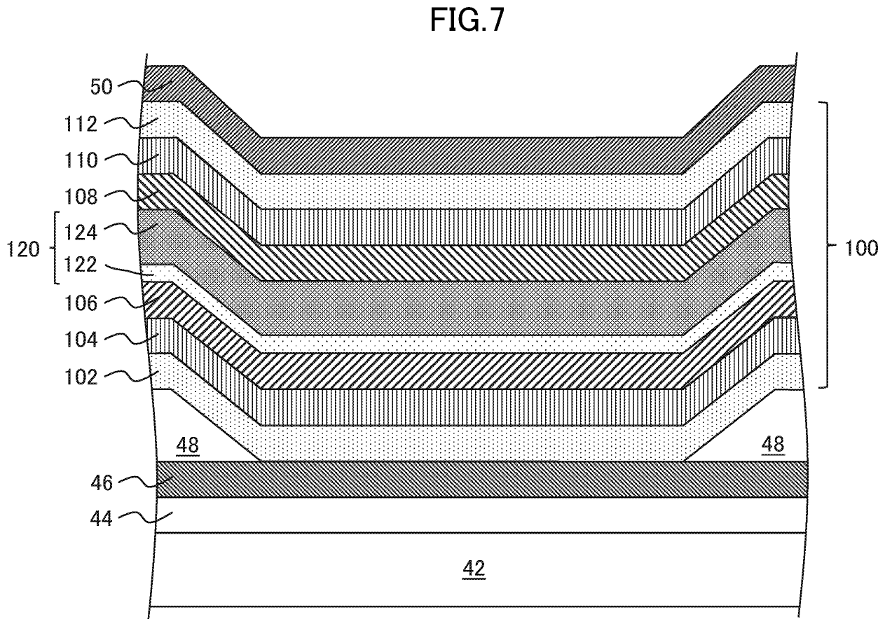

FIG. 7 is a modification example of the second example illustrated in FIG. 6. In FIG. 7, the thickness of the first light emitting layer 122 is thinner than the thickness of the second light emitting layer 124. Therefore, as illustrated in FIG. 6, it is not required that the thickness of the first light emitting layer 122 is the same as the thickness of the second light emitting layer 124. That is, it is satisfactory as long as the thickness of the first light emitting layer 122 is equal to or less than the thickness of the second light emitting layer 124. The thickness of the first light emitting layer 122 and the thickness of the second light emitting layer 124 in FIGS. 6 and 7 show relative difference between the layers. Meanwhile, the thickness of the first light emitting layer 122 and the thickness of the second light emitting layer 124 do not show the relative relationship with the thicknesses of the other layers.

As illustrated in FIGS. 6 and 7 describes above it is satisfactory as long as the first light emitting layer 122 and the second light emitting layer 124 are provided in the organic light emitting layer 120, and the first light emitting layer 122 having the low weight percent concentration of the TADF material is provided on any one electrode side. This configuration is effective in a case where the amount of the holes or electrons injected from any one electrode is larger than the amount of the electrons or the holes injected from the other electrode or the like. Specifically, it is satisfactory as long as the first light emitting layer 122 having the low weight percent concentration of the TADF material is provided on the electrode side having the larger injection amount of the holes or electrons.

Generally, the interface deterioration between the hole transport layer 104 and the organic light emitting layer 120 is known as one of the causes of the deterioration of the light emitting element. In order to prevent the deterioration, it is required to prevent the accumulation of the holes in the interface of the organic light emitting layer 120. That is, it is required to cause the light emitting position in the organic light emitting layer 120 to be far from the interface of the organic light emitting layer 120.

The structure of the organic light emitting layer 120 illustrated in the second example in FIGS. 4, 6, and 7 is a structure employed particularly for preventing the deterioration of the interface between the hole transport layer 104 and the organic light emitting layer 120. Particularly, it is possible to prevent the deterioration of the interface between the hole transport layer 104 and the organic light emitting layer 120 by providing the first light emitting layer 122 on the side of the lower electrode 46 which is the anode.

Specifically, the weight percent concentration of the TADF material on the interface of the organic light emitting layer 120 on the side of the lower electrode 46 which is the anode is lower compared with the other portions of the organic light emitting layer 120. Therefore, the light emission in the interface of the organic light emitting layer 120 on the lower electrode 46 side can be suppressed to the minimum. That is, it is possible to prevent the deterioration of the interface between the hole transport layer 104 and the organic light emitting layer 120.

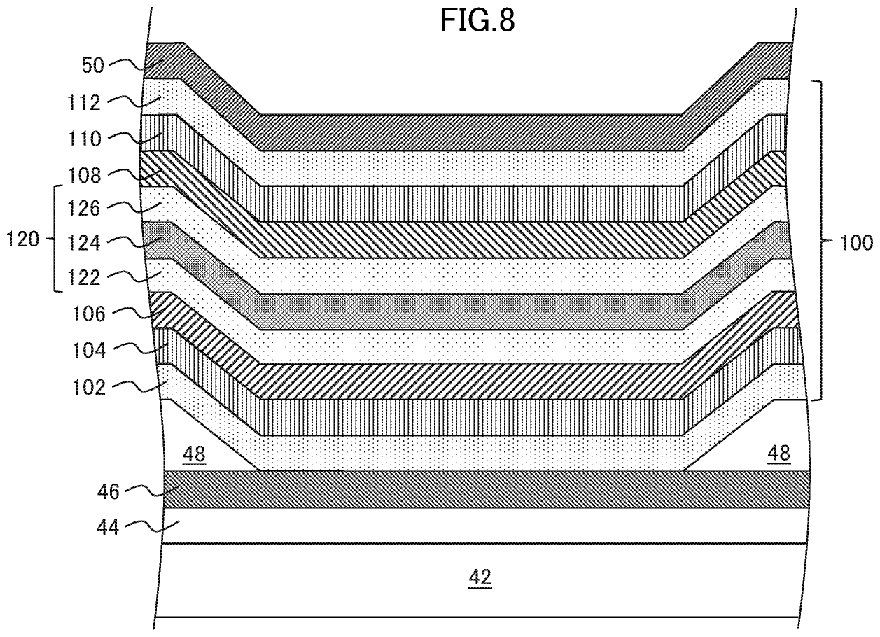

FIG. 8 is a view illustrating the structure of the light emitting unit 100 according to a third example by enlarging in the broken line portion of FIG. 3. In the third example, the organic light emitting layer 120 includes three layers of the first light emitting layer 122, the second light emitting layer 124, and a third light emitting layer 126. In FIG. 8, an example of a case where the first light emitting layer 122 is provided on the side of the lower electrode 46 which is the anode, and the third light emitting layer 126 is provided on the side of the upper electrode 50 which is the cathode is illustrated.

The weight percent concentration of the TADF material in the first light emitting layer 122 illustrated in FIG. 8 is lower than the weight percent concentration of the TADF material in the second light emitting layer 124. Correspondingly, in FIG. 8, the hatching in the first light emitting layer 122 is caused to be thinner than the hatching in the second light emitting layer 124.

The weight percent concentration of the TADF material in the third light emitting layer 126 illustrated in FIG. 8 is lower than the weight percent concentration of the TADF material in the second light emitting layer 124. Correspondingly, in FIG. 8, the hatching in the third light emitting layer 126 is caused to be thinner than the hatching in the second light emitting layer 124. In this manner, the darkness of the hatching corresponds to the height of the weight percent concentration of the TADF material.

The weight percent concentration of the TADF material in the first light emitting layer 122 is not required to be necessarily the same as the weight percent concentration of the TADF material in the third light emitting layer 126. In a case where the weight percent concentration is not the same, it is considered that the present example is the same as the second example. That is, the configuration is effective if the amount of the holes or electrons injected from any one electrode is larger than the amount of electrons or holes injected from the other electrode. For example, if the injection amount of the electrons is more than the injection amount of the holes, it is satisfactory as long as the weight percent concentration of the TADF material in the first light emitting layer 122 is caused to be lower than the weight percent concentration of the TADF material in the third light emitting layer 126. That is, it is satisfactory as long as the weight percent concentration of the TADF material in the first light emitting layer 122 is equal to or less than the weight percent concentration of the TADF material in the third light emitting layer 126.

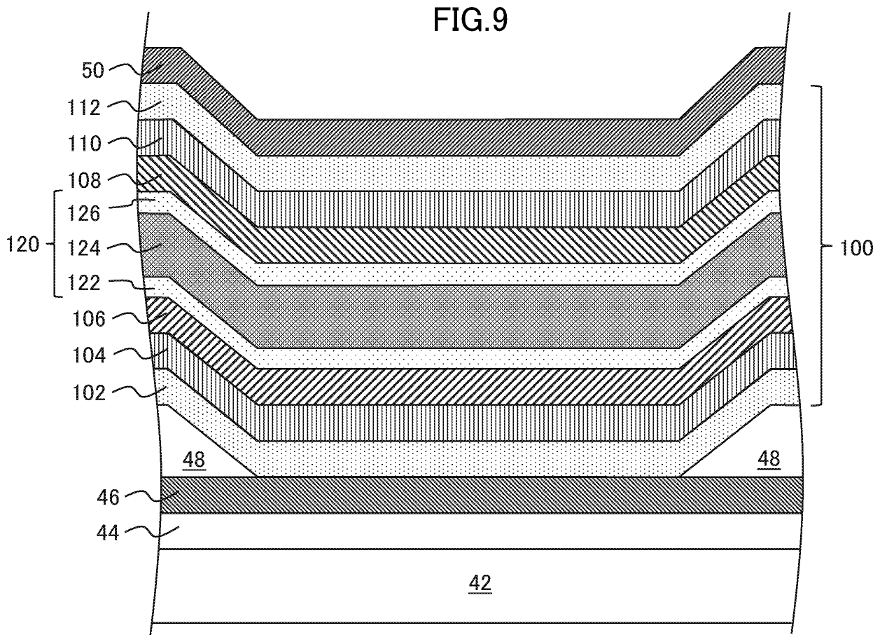

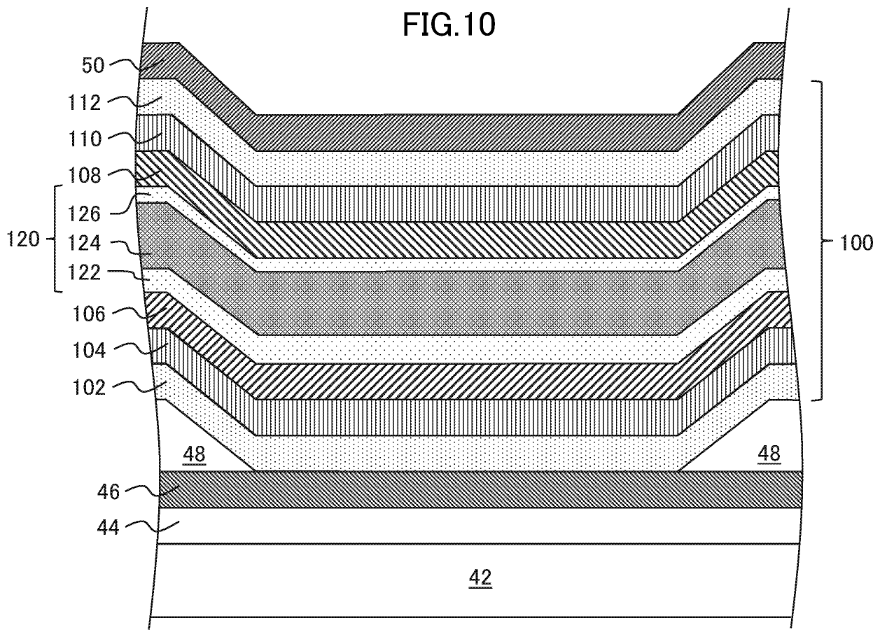

FIGS. 9 and 10 each are a modification example of the third example illustrated in FIG. 8. In FIG. 9, the thickness of the first light emitting layer 122 and the thickness of the third light emitting layer 126 are thinner than the thickness of the second light emitting layer 124. Moreover, the thickness of the first light emitting layer 122 is the same as the thickness of the third light emitting layer 126. In contrast, in FIG. 10, in comparison with FIG. 9, further, the thickness of the third light emitting layer 126 is thinner than the thickness of the first light emitting layer 122.

From the above, as illustrated in FIG. 8, the thickness of the first light emitting layer 122 and the thickness of the third light emitting layer 126 are not required to be necessarily the same as the thickness of the second light emitting layer 124. It is satisfactory as long as the thickness of the first light emitting layer 122 is equal to or less than the thickness of the second light emitting layer 124, and the thickness of the third light emitting layer 126 is equal to or less than the thickness of the second light emitting layer 124.

The thickness of the first light emitting layer 122 and the thickness of the third light emitting layer 126 are not required to be necessarily the same. In the same manner as the second example, the configuration is effective if the amount of the holes or the electrons injected from any one electrode is larger than the amount of the electrons or holes injected from the other electrode.

Also in FIG. 10, in order to prevent the deterioration of the interface between the hole transport layer 104 and the organic light emitting layer 120, the first light emitting layer 122 is provided on the side of the lower electrode 46 which is the anode. Accordingly, it is possible to cause the light emitting position in the organic light emitting layer 120 to be far from the interface of the organic light emitting layer 120, and as a result, the accumulation of the holes in the interface of the organic light emitting layer 120 can be prevented.

In FIGS. 8 to 10, the thickness of the first light emitting layer 122, the thickness of the second light emitting layer 124, and the thickness of the third light emitting layer 126 show relative differences between the layers. Meanwhile, the thickness of the first light emitting layer 122, the thickness of the second light emitting layer 124, and the thickness of the third light emitting layer 126 do not show the relative relationship with the thicknesses of the other layers.

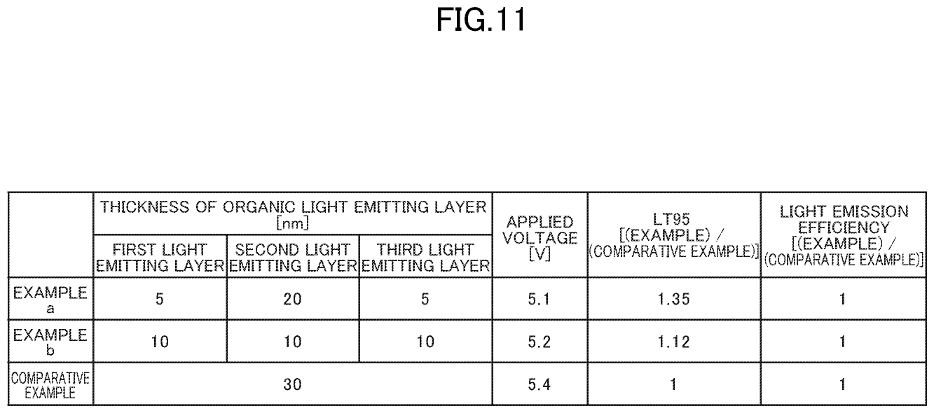

FIG. 11 is a table summarizing light emission test results of the organic EL elements in Examples a and b and Comparative Example. The layer structure of the light emitting unit 100 in Example a corresponds to FIG. 9, and the layer structure of the light emitting unit 100 in Example b corresponds to FIG. 8.

First, the thickness of each light emitting layer in the two Examples described above is described. In Example a, the thicknesses of both of the first light emitting layer 122 and the third light emitting layer 126 are set as 5 nm, and the thickness of the second light emitting layer 124 is set as 20 nm. Meanwhile, in Example b, the thicknesses of the three layers of the first light emitting layer 122 to the third light emitting layer 126 each are set as 10 nm.

Subsequently, the weight percent concentrations of the light emitting material and the TADF material included in each light emitting layer of the two Examples described above are described. In both of Examples a and b, the weight percent concentration of the light emitting material in the entire organic light emitting layer 120 is set as 2%. In both of Examples a and b, the weight percent concentrations of the TADF materials in the first light emitting layer 122 and the third light emitting layer 126 are set as 7%, and the weight percent concentration of the TADF material in the second light emitting layer 124 is set as 15%.

In Comparative Example to be compared with the above two Examples, the organic light emitting layer 120 is formed with one layer having a thickness of 30 nm in the same manner as in the related art. The weight percent concentration of the light emitting material in the organic light emitting layer 120 is set as 2%, and the weight percent concentration of the TADF material therein is set as 15%.

Moreover, with reference to the results of FIG. 11, it can be said that in both of the two Examples, the lifetime of the organic EL element is longer than that of Comparative Example having the same configuration as in the related art. Particularly, in the column of LT95 (time until the initial emission intensity of the element decreases by 5%), values standardized in [Example]/[Comparative Example] are described, and in both of Examples a and b, the value is 1 or more. Meanwhile, also in the column of the light emission efficiency, values standardized in [Example]/[Comparative Example] are described, and there is no change in the two Examples and Comparative Example.

From the above, the likeliness of the generation of the energy transfer from the TADF material to the light emitting material near the interface of the organic light emitting layer 120 that is not preferable as the light emitting position is lower than that in other portions. Therefore, in a portion where the likeliness of the generation of the energy transfer from the TADF material to the light emitting material is higher than that in a portion near the interface of the organic light emitting layer 120, the light is more securely emitted. That is, since the likeliness of the presence of the light emitting position near the intermediate portion positioned between the upper interface and the lower interface of the organic light emitting layer 120 increases as compared with the related art, it is possible to provide a display device of which a defective product having a short lifespan of the light emitting element is less likely to be produced.

The present invention is not limited to the above embodiment, and various modifications can be made. For example, the present invention can be replaced with a configuration that is substantially the same as the configuration described in the above embodiment, a configuration that exhibits the same operational effect, or a configuration that can achieve the same object.

Within the scope of the idea of the present invention, various modification examples and correction examples can be easily conceived by those skilled in the art, and it is understood that modification examples and correction examples also belong to the scope of the present invention. For example, examples obtained by appropriately performing adding, deleting, or design on the above embodiments by those skilled in the art or examples obtained by performing adding, omission, or condition change of the steps are included in the scope of the present invention, as long as examples include the gist of the present invention.

What is claimed is:

1. A display device comprising an organic light emitting element, the organic light emitting element including a thermally activated delayed fluorescence material, wherein
the organic light emitting element includes an organic light emitting layer, and
a weight percent concentration of the thermally activated delayed fluorescence material in at least one interface portion of the organic light emitting layer is lower than a weight percent concentration of the thermally activated delayed fluorescence material in an intermediate portion positioned between the one interface portion and another interface portion.

2. The display device according to claim 1, wherein
the organic light emitting layer includes a first light emitting layer and a second light emitting layer, and
a first weight percent concentration of a thermally activated delayed fluorescence material in the first light emitting layer is lower than a second weight percent concentration of the thermally activated delayed fluorescence material in the second light emitting layer.

3. The display device according to claim 2, wherein
a thickness of the first light emitting layer is equal to or less than a thickness of the second light emitting layer.

4. The display device according to claim 2, wherein
the first light emitting layer and the second light emitting layer are layered in the organic light emitting layer,
the first light emitting layer is closer to an anode than the second light emitting layer, and
the second light emitting layer is closer to a cathode than the first light emitting layer.

5. The display device according to claim 4, wherein
the organic light emitting layer further includes a third light emitting layer provided closer to the cathode than the second light emitting layer, and
a third weight percent concentration of the thermally activated delayed fluorescence material in the third light emitting layer is lower than a second weight percent concentration of a thermally activated delayed fluorescence material in the second light emitting layer.

6. The display device according to claim 5, wherein
a thickness of the third light emitting layer is equal to or less than a thickness of the second light emitting layer.

7. The display device according to claim 6,
wherein a thickness of the third light emitting layer is equal to or less than a thickness of the first light emitting layer.

8. The display device according to claim 6, wherein
a thickness of the first light emitting layer is the same as a thickness of the third light emitting layer.

9. The display device according to claim 5, wherein
the first weight percent concentration of the thermally activated delayed fluorescence material is equal to or less than the third weight percent concentration of the thermally activated delayed fluorescence material.

10. The display device according to claim 1, wherein
a weight percent concentration of a light emitting material in the organic light emitting layer is lower than the weight percent concentration of the thermally activated delayed fluorescence material in the organic light emitting layer.
